(19) United States
(12) Patent Application Publication
(10) Pub. No.: US 2025/0003072 A1
(43) Pub. Date: Jan. 2, 2025

(54) HIGH PURITY MOLYBDENUM-CONTAINING PRECURSORS AND RELATED SYSTEMS AND METHODS

(71) Applicant: ENTEGRIS, INC., Billerica, MA (US)

(72) Inventors: Joseph E. Reynolds, III, Leander, TX (US); Michael Watson, Leander, TX (US); Bryan C. Hendrix, Danbury, CT (US); Sara Moghaddam, Dripping Springs, TX (US); Devon N. Dion, Nashua, NH (US); Benjamin R. Garrett, Leander, TX (US); Carlo Waldfried, Middleton, MA (US); Virendra Warke, North Chelmsford, MA (US)

(21) Appl. No.: 18/755,011

(22) Filed: Jun. 26, 2024

Related U.S. Application Data
(60) Provisional application No. 63/523,612, filed on Jun. 27, 2023.

(51) Int. Cl. C23C 16/455; C23C 16/44

(52) U.S. Cl. CPC C23C 16/45553; C23C 16/4404; C23C 16/45561

(57) ABSTRACT

High purity molybdenum-containing precursors and related systems and methods are provided. A precursor delivery system comprises a vaporizer vessel that is configured to contain a vaporizable precursor that, when vaporized, produces a precursor vapor. The precursor delivery system comprises at least one protective surface treatment. The at least one protective surface treatment covers a sufficient amount of at least one gas-exposed surface of the precursor delivery system to reduce an amount of at least one contaminant in the precursor vapor as compared to a precursor vapor produced by a precursor delivery system without the at least one protective surface treatment.

### CROSS-REFERENCE TO RELATED APPLICATIONS

This application claims the benefit under 35 USC 119 of U.S. Provisional Patent Application No. 63/523,612, filed Jun. 27, 2023, the disclosure of which is hereby incorporated herein by reference in its entirety.

### FIELD

The present disclosure relates to molybdenum-containing precursors with high purity, as well as systems and methods relating thereto.

### BACKGROUND

The presence of contaminants in precursor vapors is undesirable in precursor delivery applications, such as, applications relating to semiconductor fabrication and manufacturing. Reducing the presence of contaminants in the precursor vapors remains an ongoing challenge.

### SUMMARY

Some embodiments relate to a precursor delivery system. In some embodiments, the precursor delivery system comprises a vaporizer vessel. In some embodiments, the vaporizer vessel is configured to contain a vaporizable precursor that, when vaporized, produces a precursor vapor. In some embodiments, the precursor delivery system comprises at least one protective surface treatment. In some embodiments, the at least one protective surface treatment covers a sufficient amount of at least one gas-exposed surface of the precursor delivery system to reduce an amount of at least one contaminant in the precursor vapor as compared to a precursor vapor produced by a precursor delivery system without the at least one protective surface treatment.

Some embodiments relate to a method of precursor delivery. In some embodiments, the method of delivering the precursor vapor comprises obtaining a precursor delivery system. In some embodiments, the precursor delivery system comprises a vaporizer vessel containing a vaporizable precursor. In some embodiments, the vaporizer vessel comprises at least one protective surface treatment covering at least a portion of at least one gas-exposed surface of the vaporizer vessel. In some embodiments, the method of delivering the precursor vapor comprises vaporizing at least a portion of the vaporizable precursor to produce a precursor vapor. In some embodiments, the method of delivering the precursor vapor comprises flowing the precursor vapor from the vaporizer vessel to a semiconductor processing tool. In some embodiments, the at least one protective surface treatment covers a sufficient amount of the at least one gas-exposed surface of the precursor delivery system to reduce an amount of at least one contaminant in the precursor vapor as compared to a precursor vapor produced by a precursor delivery system without the at least one protective surface treatment.

### DRAWINGS

Some embodiments of the disclosure are herein described, by way of example only, with reference to the accompanying drawings. With specific reference now to the drawings in detail, it is stressed that the embodiments shown are by way of example and for purposes of illustrative discussion of embodiments of the disclosure. In this regard, the description taken with the drawings makes apparent to those skilled in the art how embodiments of the disclosure may be practiced.

FIG. 1 is a schematic diagram of a precursor delivery systems, according to some embodiments.

FIG. 2 is a cross-sectional view of a vaporizer vessel, according to some embodiments.

FIG. 3 is a schematic diagram of a flowchart of a method of precursor delivery, according to some embodiments.

FIG. 4 is a graphical view illustrating iron contamination levels in molybdenum-containing precursors in coated versus uncoated systems, according to some embodiments.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

Any prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may.

Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

Delivery of vapor precursors at elevated temperatures and elevated pressures may increase contamination levels, for example and without limitation, metal and/or particle contaminant levels, due to corrosion and leaching, among other things. As disclosed herein, in some embodiments, protective surface treatments are applied to one or more gas-exposed surfaces of a precursor delivery system so as to reduce corrosion, leaching, and particle contamination, thereby increasing purity of the precursor vapor. It has unexpectedly been discovered that the presence of protective surface treatments on gas-exposed surfaces of the precursor delivery systems can markedly improve purity levels (i.e., markedly reduce contamination levels) for various vapor precursors, including, for example and without limitation, molybdenum-containing precursor vapors. The precursor delivery systems disclosed herein provide numerous other advantages, including, for example and without limitation, improved performance at elevated temperatures and/or pressures, among other process conditions. These shall not be limiting as these and other advantages of the embodiments disclosed herein will become apparent from the disclosure herein.

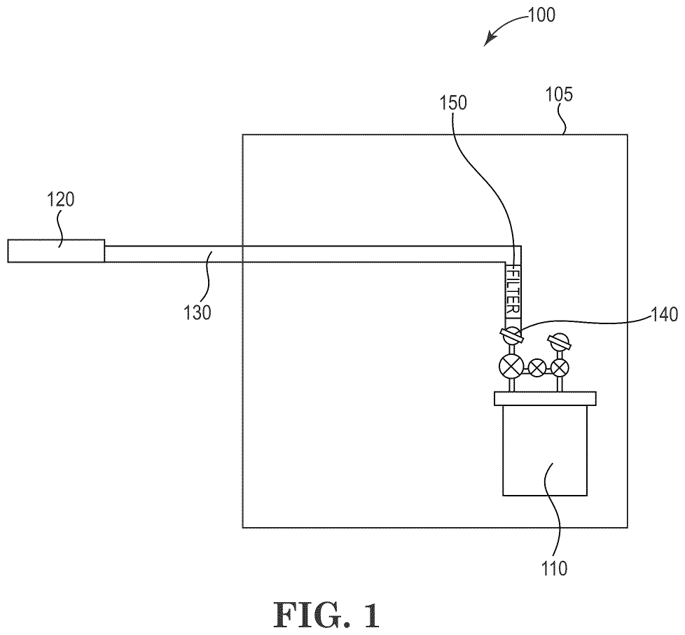

FIG. 1 is a schematic diagram of a precursor delivery system 100, according to some embodiments. As shown in FIG. 1, in some embodiments, the precursor delivery system 100 comprises a vaporizer vessel 110. In some embodiments, the vaporizer vessel 110 is fluidly coupled to a semiconductor processing tool 120. In some embodiments, the vaporizer vessel 110 is fluidly coupled to the semiconductor processing tool 120 via a gas supply line 130. In some embodiments, a valve assembly 140 fluidly couples the vaporizer vessel 110 to the gas supply line 130. In some embodiments, at least one filter 150 is located in the gas supply line 130. That is, in some embodiments, the at least one filter 150 is located in a flow path of the precursor vapor such that at least a portion of the precursor vapor flows through the at least one filter 150. In some embodiments, the at least one filter 150 comprises at least one particle filter for particle removal from the precursor vapor. In some embodiments, at least the vaporizer vessel 110 is located in a housing 105, such as, for example and without limitation, a gas supply cabinet or other enclosure. Other components of the precursor delivery system 100 may be included in the housing 105 without departing from the scope of this disclosure.

The vaporizer vessel 110 may be configured to contain a vaporizable precursor that, when vaporized, produces a precursor vapor. The precursor delivery system 100 may comprise at least one protective surface treatment that covers at least a portion of the gas-exposed surfaces of the precursor delivery system 100. As used herein, the term “protective surface treatment” includes, for example and without limitation, at least one of a coating, a modified surface region, a passivated surface region, or any combination thereof. As used herein, the term “gas-exposed surface(s)” refers to any surface of the precursor delivery system 100 that is or may be exposed to at least one of a gas, a vapor, or any combination thereof. For example, in some embodiments, a gas-exposed surface is any surface in fluid communication with at least one of a gas, a vapor, or any combination thereof, at any point during use or nonuse of the precursor delivery system 100.

In some embodiments, the at least one protective surface treatment comprises a modified surface region. For example, in some embodiments, at least a portion of the gas-exposed surface comprises a modified surface region. In some embodiments, the at least one protective surface treatment is a surface modification in which the gas-exposed surface is modified (e.g., passivated) via exposure to a reactive vapor. In other words, the surface modification is not, for example, a coating applied to the gas-exposed surface; the surface modification is the gas-exposed surface that has been chemically modified via exposure to the reactive vapor. In some embodiments, the surface region that is chemically modified is referred to herein as the modified surface region and/or passivated surface region.

In some embodiments, the at least one protective surface treatment covers a sufficient amount of at least one gas-exposed surface of the precursor delivery system to reduce an amount of at least one contaminant in the precursor vapor, as compared to a precursor vapor produced by a precursor delivery system without the at least one protective surface treatment but which is otherwise same or similar to the precursor delivery system comprising the at least one protective surface treatment. In some embodiments, the at least one protective surface treatment covers at least one non-gas-exposed surface of the precursor delivery system. That is, in some embodiments, the at least one protective surface treatment covers surfaces of the precursor delivery system which are not exposed to any gas. In some embodiments, a non-gas-exposed surface of the precursor delivery system is covered by a source reagent, which, when vaporized, results in exposing the underlying surface. In some embodiments, these surfaces are included in the gas-exposed surfaces of the precursor delivery system. The at least one protective surface treatment may cover all or at least a portion of the gas-exposed surfaces of the precursor delivery system 100. Each of the at least one protective surface treatment may be the same or different and, for example, may vary with the material of construction of each component of the precursor delivery system 100, the vaporizable precursor and/or precursor vapor produced or being produced, and/or the conditions of operation (e.g., temperature, pressure, etc. under which the vaporizable precursor is vaporized), among other things. In some embodiments, the at least one protective surface treatment covers at least a portion of at least one gas-exposed surface of the precursor delivery system 100. That is, in some embodiments, the at least one protective surface treatment covers at least a portion or only a portion of the at least one gas-exposed surface of the precursor delivery system 100. In some embodiments, the at least one protective surface treatment covers the precursor delivery system 100 in its entirety, or all gas-exposed surfaces of the precursor delivery system 100. That is, in some embodiments, the at least one protective surface treatment covers all surfaces and/or all gas-exposed surfaces of the precursor delivery system 100.

In some embodiments, the at least one protective surface treatment covers at least a portion of the gas-exposed surfaces of the vaporizer vessel (as disclosed in further detail below). In some embodiments, the at least one protective surface treatment covers all of the gas-exposed surfaces of the vaporizer vessel (as disclosed in further detail below). In some embodiments, at least a portion of at least one gas-exposed surface of the gas supply line is covered by the at least one protective surface treatment. In some embodiments, the at least one protective surface treatment covers all gas-exposed surfaces of the gas supply line. In some embodiments, at least a portion of at least one gas-exposed surface of the at least one filter is covered by the at least one protective surface treatment. In some embodiments, the at least one protective surface treatment covers all gas-exposed surfaces of the at least one filter. In some embodiments, at least a portion of at least one gas-exposed surface of the valve assembly is covered by the at least one protective surface treatment. In some embodiments, the at least one protective surface treatment covers all gas-exposed surfaces of the valve assembly. In some embodiments, the at least one protective surface treatment covers at least a portion of gas-exposed surfaces of other components of the precursor delivery system 100 including, for example and without limitation, at least one of orifices, tubes, gaskets, fittings, sensors (e.g., pressure sensors, temperature sensors, flow rate sensors, etc.), fasteners, or any combination thereof, among others.

In some embodiments, the at least one protective surface treatment comprises a plurality of protective surface treatments, wherein each surface of the precursor delivery system is independently covered by one or more of the plurality of protective surface treatments. For example, in some embodiments, at least one surface of the precursor delivery system comprises a first protective surface treatment on the surface of the precursor delivery system, and at least a second protective surface treatment on the first protective surface treatment. In some embodiments, for example, the surface of the precursor delivery system comprises a surface modified region (e.g., in which MgF₂ is formed in the surface; not a coating) and a coating (e.g., an ALD coating) on the surface modified region. In some embodiments, at least a first surface of the precursor delivery system comprises a first protective surface treatment and at least a second surface of the precursor delivery system comprises a second protective surface treatment, wherein the first protective surface treatment and the second protective surface treatment are different (or same or similar). In some embodiments, the at least one protective surface treatment directly contacts the gas-exposed surface. In some embodiments, the at least one protective surface treatment is a surface modification in which the gas-exposed surface is modified (e.g., passivated) via exposure to a reactive vapor. In other words, the surface modification is not a coating applied to the gas-exposed surface; the surface modification is the gas-exposed surface that has been chemically modified via exposure to the reactive vapor. In some embodiments, an intervening layer is located between the gas-exposed surface and the at least one protective surface treatment. The at least one protective surface treatment may comprise a protective surface treatment material that reduces degradation of the gas-exposed surface such that contaminants are not introduced, or at least the amount of contaminants is reduced, into the precursor vapor during use or nonuse of the precursor delivery system. Contaminants may be introduced by at least one of corrosion, leaching, particle contamination, or any combination thereof, of the gas-exposed surface due to exposure, optionally at elevated temperatures and/or pressures, to precursor vapor(s), among other things. In some embodiments, the protective surface treatment material of the at least one protective surface treatment is a material or substance which is not reactive with the precursor vapor (e.g., an inert material relative to the precursor vapor under the conditions of vaporizing).

In some embodiments, the at least one protective surface treatment comprises an oxide coating. In some embodiments, the at least one protective surface treatment comprises at least one of nickel, Al₂O₃, Cr₂O₃, gold, nitrides such as titanium nitride (TiN), glasses, copper, or any combination thereof. In some embodiments, passivation with germanium tetrafluoride is effective for stainless steel and nickel due to the formation of surface Ni—F, Cr—F, and Fe—F species, which can be considered as NiF₂, CrF₃, or FeF₃ layers overlying nickel or stainless steel.

In some embodiments, the at least one protective surface treatment comprises metals such as nickel and metal alloys. In other embodiments, the at least one protective surface treatment comprises polymeric materials, such as polytetrafluoroethylene (PTFE) or PTFE-like materials, including protective coatings of materials commercially available under the trademarks Teflon® and Kalrez®. In some embodiments, the at least one protective surface treatment may also be formed of or otherwise comprise materials such as aluminum, copper, or gold.

In some embodiments, the at least one protective surface treatment comprises an atomic layer deposition (ALD) coating. In some embodiments, the ALD coating may comprise yttria. In some embodiments, the ALD coating may comprise zirconia. In some embodiments, the ALD coating may comprise titania. In some embodiments, the ALD coating may comprise AlOₓN_{y}, where x is 1 to 5 and y is 1 to 5. In some embodiments, the at least one protective surface treatment comprises at least one of a thermal atomic layer deposition (ALD) coating, a physical vapor deposition (PVD) coating, a chemical vapor deposition (CVD) coating, a solution deposition coating, or any combination thereof.

In some embodiments, the at least one protective surface treatment comprises at least one of alumina, yttria, titania, zirconia, tantalum oxide, or any combination thereof. In some embodiments, the at least one gas-exposed surface is fluorinated, without application of a coating on the at least one gas-exposed surface. In some embodiments, the fluorinated gas-exposed surface may be formed by fluorinating the gas-exposed surface such that the gas-exposed surface is modified so as to comprise at least one of YOF, YF₃, or any combination thereof.

In some embodiments, the at least one protective surface treatment comprises an oxide of formula MO, wherein M is Ca, Mg, or Be; an oxide of formula M′O₂, wherein M′ is a stoichiometrically acceptable metal; an oxide of formula Re₂O₃, wherein Re is a rare earth element; or an oxide of formula TaₓO_{y}, where x is greater than 0 and y is greater than 0. In some embodiments, the at least one protective surface treatment comprises a metal oxide of the formula Ln₂O₃, wherein Ln is a lanthanide element.

In some embodiments, the at least one protective surface treatment comprises at least one of a metal nitride, a metal fluoride, or any combination thereof. In some embodiments, the at least one protective surface treatment comprises at least one of an aluminum-oxy nitride; an yttria-alumina; a silicon oxide; a silicon oxy-nitride; a transition metal oxide; a transition metal oxy-nitride; a rare earth metal oxide; a rare earth metal oxy-nitrides; or any combination thereof. In some embodiments, the metal fluoride comprises at least one of MgF₂, AlF₃, NiF₂, or any combination thereof.

In some embodiments, the at least one protective surface treatment may comprise at least one of elemental metal, a metal alloy, a metal compound (e.g., a metal oxide compound), or any combination thereof. In some embodiments, the at least one protective surface treatment comprises at least one of magnesium, aluminum, vanadium, iron, nickel, chromium, zinc, molybdenum, titanium, lithium, copper, manganese, or any combination thereof. In some embodiments, the at least one protective surface treatment comprises at least one of magnesium, aluminum, vanadium, iron, nickel, chromium, zinc, molybdenum, titanium, lithium, copper, manganese, silicon, copper, magnesium oxide, or any combination thereof.

In some embodiments, the at least one protective surface treatment comprises at least one of titania, yttria, alumina, zirconia, tantalum oxide, or any combination thereof. In some embodiments, the at least one protective surface treatment comprises at least one of Al₂O₃; oxides of the formula MO, wherein M is Ca, Mg, or Be; oxides of the formula M′O₂, wherein M′ is a stoichiometrically acceptable metal; and oxides of the formula Re₂O₃, wherein Re is a rare earth element, such as, for example, a lanthanide element; and oxides of formula TaₓO_{y}, where x is greater than 0 and y is greater than 0. In some embodiments, the lanthanide element may comprise, consist of, or consist essentially of La, Sc, or Y. In some embodiments, the protective surface treatment layer may comprise, consist of, or consist essentially of, or may be selected from the group consisting of, at least one of alumina, aluminum-oxy nitride, yttria, yttria-alumina, silicon oxide, silicon oxy-nitride, transition metal oxides, transition metal oxy-nitrides, rare earth metal oxides, rare earth metal oxy-nitrides, or any combination thereof. In some embodiments, the method further comprises fluorinating the protective surface treatment layer to form a coating layer comprising at least one of YOF, YF₃, or any combination thereof.

In some embodiments, the at least one protective surface treatment is a reaction product of a surface with a reactive gas phase. In some embodiments, the reactive gas phase may comprise a fluorine component. In some embodiments, the reactive gas phase may comprise a molecular fluorine source vapor, which may be derived from a liquid or solid. In some embodiments, the fluorine component may comprise, consist of, or consist essentially of molecular fluorine. In some embodiments, the fluorine component is not ionic, substantially not ionic, not processed (e.g., by adding energy other than heat) to form plasma, or any combination thereof. In some embodiments, the fluorine component may comprise, consist of, or consist essentially of at least one of a fluorinated organic compound, a perfluorinated organic compound, or any combination thereof. In some embodiments, for example, the fluorine component may comprise, consist of, or consist essentially of at least one of a fluorinated alkane, a perfluorinated alkane, a fluorinated alkene, a perfluorinated alkene, or any combination thereof, wherein any one or more of which may be linear or branched. In some embodiments, the fluorine component may comprise, consist of, or consist essentially of, or may be selected from the group consisting of, at least one of CF₄, C₂F₄, C₃F₆, C₄F₈, CHF₃, C₂H₂F₂, C₂F₆, HF, CH₃F, or any combination thereof. In some embodiments, the reactive gas phase is distinct from plasma, processes for generating plasma, or any combination thereof.

In some embodiments, the reactive gas phase may comprise a gaseous fluorinated polymer derived from a non-gaseous fluorinated polymer (e.g., a solid or a liquid phase fluorinated polymer). In some embodiments, the fluorinated polymer may be a homopolymer or a copolymer. In some embodiments, the fluorinated polymer may comprise a copolymer of at least one fluoroolefin monomer and optionally at least one non-fluorinated co-monomer. In some embodiments, the fluorinated polymer may be fluorinated (i.e., partially fluorinated), perfluorinated, or may include non-fluorine halogen atoms, such as, for example and without limitation, chlorine. In some embodiments, a molecular fluorine source may be liquid or solid at room temperature, but that vaporizes at the process temperatures disclosed herein. Non-limiting examples of fluoropolymers include, without limitation, at least one of the following: polymerized perfluoroalkylethylene having a C1-C10 perfluoroalkyl group; polytetrafluoroethylene (PTFE); tetrafluoroethylene/perfluoro(alkyl vinyl ether) copolymer (PFA); tetrafluoroethylene/hexafluoropropylene copolymer (FEP); tetrafluoroethylene/perfluoro(alkyl vinyl ether)/hexafluoropropylene copolymer (EPA); polyhexafluoropropylene; ethylene/tetrafluoroethylene copolymer (ETFE); poly trifluoroethylene; polyvinylidene fluoride (PVDF); polyvinyl fluoride (PVF); polychlorotrifluoroethylene (PCTFE); ethylene/chlorotrifluoroethylene copolymer (ECTFE); or any combination thereof.

In some embodiments, the at least one protective surface treatment (e.g., a surface modified region, passivated region, or any combination thereof) comprises at least one of a metal nitride, a metal fluoride, or any combination thereof. In some embodiments, the at least one protective surface treatment (e.g., a surface modified region, passivated region, or any combination thereof) comprises at least one of an aluminum-oxy nitride; an yttria-alumina; a silicon oxide; a silicon oxy-nitride; a transition metal oxide; a transition metal oxy-nitride; a rare earth metal oxide; a rare earth metal oxy-nitrides; or any combination thereof. In some embodiments, the metal fluoride comprises at least one of MgF₂, AlF₃, NiF₂, or any combination thereof.

In some embodiments, the at least one protective surface treatment is a conformal layer. In some embodiments, the at least one protective surface treatment is a layer having a substantially uniform thickness or a uniform thickness. In some embodiments, the at least one protective surface treatment may be a corrosion resistant layer or may form a corrosion resistant substrate surface. In some embodiments, the at least one protective surface treatment may passivate the surface of the substrate. In some embodiments, the at least one protective surface treatment may be a protective layer.

In some embodiments, the at least one protective surface treatment may have a thickness of 1 nm to 50 μm, or any range or subrange therebetween. For example, in some embodiments, the protective surface treatment layer may have a thickness of less than 5 μm, less than 1 μm, or less than 250 nm. In some embodiments, the protective surface treatment layer may have a thickness of 100 nm to 250 nm, 1 nm to 4 μm, 1 nm to 3 μm, 1 nm to 2 μm, 1 nm to 1 μm, 1 nm to 900 nm, 1 nm to 850 nm, 1 nm to 800 nm, 1 nm to 750 nm, 1 nm to 700 nm, 1 nm to 650 nm, 1 nm to 600 nm, 1 nm to 550 nm, 1 nm to 450 nm, 1 nm to 400 nm, 1 nm to 350 nm, 1 nm to 300 nm, 1 nm to 250 nm, 1 nm to 200 nm, 1 nm to 150 nm, 1 nm to 100 nm, 1 nm to 50 nm, 50 nm to 5 μm, 100 nm to 5 μm, 200 nm to 5 μm, 300 nm to 5 μm, 400 nm to 5 μm, 500 nm to 5 μm, 600 nm to 5 μm, 700 nm to 5 μm, 800 nm to 5 μm, 900 nm to 5 μm, 1 μm to 5 μm, 2 μm to 5 μm, 3 μm to 5 μm, 4 μm to 5 μm, 1 nm to 750 nm, 1 nm to 500 nm, 2 nm to 500 nm, 1 nm to 250 nm, 20 nm to 125 nm, 20 nm to 250 nm, 20 nm to 500 nm, 50 nm to 500 nm, 50 nm to 400 nm, 50 nm to 300 nm, 50 nm to 200 nm, 15 nm to 200 nm, 20 nm to 50 nm, 10 nm to 40 nm, 30 nm to 50 nm, 1 nm to 5 μm, 1 μm to 5 μm, 1 μm to 4 μm, 1 μm to 3 μm, 1 μm to 2 μm, 5 nm to 5 μm, 1 nm to 1 μm, and/or any range or subrange therebetween.

In some embodiments, the at least one protective surface treatment comprises a protective surface treatment formed by a vapor deposition process. Examples of vapor deposition processes include, without limitation, at least one of a chemical vapor deposition (CVD) process, a digital or pulsed chemical vapor deposition process, a plasma-enhanced cyclical chemical vapor deposition process (PECCVD), a flowable chemical vapor deposition process (FCVD), an atomic layer deposition (ALD) process, a thermal atomic layer deposition, a plasma-enhanced atomic layer deposition (PEALD) process, a metal organic chemical vapor deposition (MOCVD) process, a plasma-enhanced chemical vapor deposition (PECVD) process, or any combination thereof.

When vaporizing the vaporizable precursor using the precursor delivery system 100, precursor vapor with high purity is produced. In some embodiments, the vaporizable precursor is a molybdenum-containing source reagent that, when vaporized, produces a molybdenum-containing precursor. In some embodiments, the molybdenum-containing source reagent and/or molybdenum-containing precursor comprises at least one of molybdenum pentachloride (MoCl₅), a molybdenum oxychloride, a molybdenum chloride (other than MoCl₅), a molybdenum oxide, or any combination thereof. In some embodiments, the molybdenum-containing source reagent and/or molybdenum-containing precursor comprises at least one of molybdenum tetrachloride (MoCl₄), molybdenum oxytetrachloride (MoOCl₄), molybdenum dioxydichloride (MoO₂Cl₂), molybdenum dioxydichloride (MoO₂Cl₂(H₂O)), molybdenum trioxide (MoO₃), or any combination thereof. In some embodiments, the molybdenum-containing source reagent and/or molybdenum-containing precursor comprises at least one of molybdenum tetrachloride (MoCl₄), molybdenum trioxide (MoO₃), or any combination thereof. In some embodiments, the molybdenum-containing source reagent and/or molybdenum-containing precursor comprises at least one of molybdenum oxytetrachloride (MoOCl₄), molybdenum dioxydichloride (MoO₂Cl₂), molybdenum dioxydichloride (MoO₂Cl₂(H₂O)), or any combination thereof. In some embodiments, the molybdenum-containing precursor is a precursor vapor, precursor gas, or any combination thereof. In some embodiments, the precursor vapor comprises MoO₂Cl₂ vapor. In some embodiments, the precursor vapor comprises MoCl₅ vapor.

In some embodiments, the precursor vapor comprises less than 10 ppm of at least one contaminant, less than 9 ppm of at least one contaminant, less than 8 ppm of at least one contaminant, less than 7 ppm of at least one contaminant, less than 6 ppm of at least one contaminant, less than ppm of at least one contaminant, less than 5 ppm of at least one contaminant, less than 4 ppm of at least one contaminant, less than 3 ppm of at least one contaminant, less than 2 ppm of at least one contaminant, less than 1 ppm of at least one contaminant, less than 0.5 ppm of at least one contaminant, less than 0.1 ppm of at least one contaminant, less than 0.01 ppm of at least one contaminant, less than 0.009 ppm of at least one contaminant, less than 0.008 ppm of at least one contaminant, less than 0.007 ppm of at least one contaminant, less than 0.006 ppm of at least one contaminant, less than 0.005 ppm of at least one contaminant, less than 0.004 ppm of at least one contaminant, less than 0.003 ppm of at least one contaminant, less than 0.002 ppm of at least one contaminant, or less than 0.001 ppm of at least one contaminant.

In some embodiments, less than a specified amount of at least one contaminant may refer to all contaminants. For example, in some embodiments, less than 10 ppm of at least one contaminant may mean the combined total of all contaminants is less than 10 ppm. In some embodiments, less than a specified amount of at least one contaminant may refer to individual contaminants. For example, in some embodiments, less than 10 ppm of at least one contaminant may mean a first contaminant is present in an amount of less than 10 ppm, a second contaminant is present in an amount of less than 10 ppm, and so on, wherein the combined total of the first contaminant and the second contaminant may, but is not required, exceed 10 ppm.

In some embodiments, the precursor vapor comprises between 0.0001 ppm to 10 ppm of the at least one contaminant, or any range or subrange between 0.0001 ppm and 10 ppm. For example, in some embodiments, the precursor vapor comprises between 0.0001 ppm to 10 ppm, 0.0001 ppm to 9 ppm, 0.0001 ppm to 8 ppm, 0.0001 ppm to 7 ppm, 0.0001 ppm to 6 ppm, 0.0001 ppm to 5 ppm, 0.0001 ppm to 4 ppm, 0.0001 ppm to 3 ppm, 0.0001 ppm to 2 ppm, 0.0001 ppm to 1 ppm, 0.0001 ppm to 0.9 ppm, 0.0001 ppm to 0.8 ppm, 0.0001 ppm to 0.7 ppm, 0.0001 ppm to 0.6 ppm, 0.0001 ppm to 0.5 ppm, 0.0001 ppm to 0.4 ppm, 0.0001 ppm to 0.3 ppm, 0.0001 ppm to 0.2 ppm, 0.0001 ppm to 0.1 ppm, 0.0001 ppm to 0.01 ppm, 0.0001 ppm to 0.009 ppm, 0.0001 ppm to 0.008 ppm, 0.0001 ppm to 0.007 ppm, 0.0001 ppm to 0.006 ppm, 0.0001 ppm to 0.005 ppm, 0.0001 ppm to 0.004 ppm, 0.0001 ppm to 0.003 ppm, 0.0001 ppm to 0.002 ppm, 0.0001 ppm to 0.001 ppm, 0.0001 ppm to 10 ppm, 0.001 ppm to 10 ppm, 0.01 ppm to 10 ppm, 0.1 ppm to 10 ppm, 1 ppm to 10 ppm, 2 ppm to 10 ppm, 3 ppm to 10 ppm, 4 ppm to 10 ppm, 5 ppm to 10 ppm, 6 ppm to 10 ppm, 7 ppm to 10 ppm, 8 ppm to 10 ppm, or 9 ppm to 10 ppm of the at least one contaminant.

In some embodiments, a range of a specified amount of at least one contaminant may refer to all contaminants. For example, in some embodiments, 0.0001 ppm to 10 ppm of at least one contaminant may mean the combined total of all contaminants is present in a range of 0.0001 ppm to 10 ppm. In some embodiments, a range of a specified amount of at least one contaminant may refer to individual contaminants. For example, in some embodiments, 0.0001 ppm to 10 ppm of at least one contaminant may mean a first contaminant is present in an amount of 0.0001 ppm to 10 ppm, a second contaminant is present in an amount of 0.0001 ppm to 10 ppm, and so on, wherein the combined total of the first contaminant and the second contaminant may, but is not required, exceed 10 ppm.

In some embodiments, the amount of the at least one contaminant is the amount present in the precursor vapor after 180 days exposure at a temperature of at least 100° C. In some embodiments, the amount of the at least one contaminant is the amount present in the precursor vapor after 1 day to 180 days (or any range or subrange between 1 day and 180 days) exposure at a temperature of 100° C. to 1000° C. In some embodiments, the amount of the at least one contaminant is the amount present in the precursor vapor after 180 days exposure at a temperature of 120° C. to 200° C., 120° C. to 190° C., 120° C. to 180° C., 120° C. to 170° C., 120° C. to 160° C., 120° C. to 150° C., 120° C. to 140° C., 120° C. to 130° C., 130° C. to 200° C., 140° C. to 200° C., 150° C. to 200° C., 160° C. to 200° C., 170° C. to 200° C., 180° C. to 200° C., or 190° C. to 200° C.

In some embodiments, the at least one contaminant comprises at least one iron (Fe) contaminant, at least one nickel (Ni) contaminant, or any combination thereof. In some embodiments, the at least one contaminant comprises any contaminant, impurity, whether a gas, a vapor, or a solid (e.g., a particle), or other substance that reduces the purity of the precursor vapor. In some embodiments, the at least one iron contaminant comprises at least one of iron chlorides, iron oxides, iron oxychlorides, iron hydroxychlorides, or any combination thereof. In some embodiments, the at least one nickel contaminant comprises at least one of nickel chlorides, nickel oxides, nickel oxychlorides, nickel hydroxychlorides, or any combination thereof.

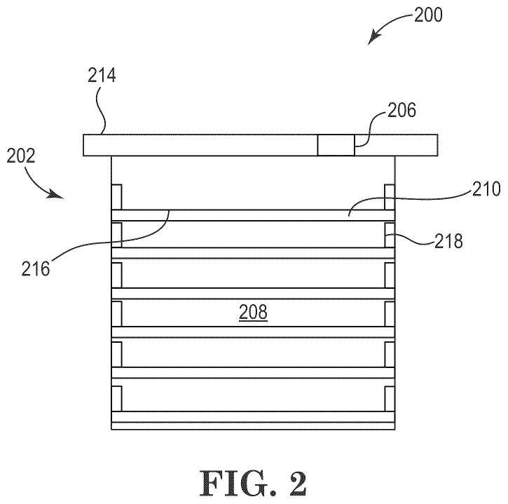

FIG. 2 is a cross-sectional view of a vaporizer vessel 200, according to some embodiments. The vaporizer vessel 200 may comprise a vessel 202 having an inlet 204 and an outlet 206. The vessel 202 may define an interior volume 208 of the vaporizer vessel 200. In some embodiments, the vessel 102 is fully enclosed. In some embodiments, the vessel 202 comprises a lid 214 coupled or removably coupled to a vessel body, wherein the lid 214, when mated with the vessel body, defines the interior volume 208 of the vaporizer vessel 200. In some embodiments, at least one of the inlet 204, the outlet 206, or any combination thereof, is located in the lid 214. The vessel 202 may contain or may be configured to contain a vaporizable precursor, which, when vaporized, produces a precursor vapor, such as, for example and without limitation, a molybdenum-containing vapor, that is dischargeable through the outlet. In some embodiments, the vaporizer vessel 200 comprises at least one tray 210 located within the interior volume 208 of the vessel 202. In some embodiments, the at least one tray 210 is configured to contain the vaporizable precursor. At least one of the at least one tray 210 may comprise a base 216, and a sidewall 218 extending upwards from an outer edge of the base 216. The at least one tray 210 may be configured to contact an inner surface of the vessel 202.

In some embodiments, the protective surface treatment covers the vaporizer vessel 200 in its entirety. For example, in some embodiments, the protective surface treatment covers all gas-exposed surfaces of the vaporizer vessel 200. In some embodiments, the protective surface treatment covers only a portion of the gas-exposed surfaces of the vaporizer vessel 200. In some embodiments, the protective surface treatment covers at least a portion of the inlet 204 of the vaporizer vessel 200. In some embodiments, the protective surface treatment covers at least a portion of the gas exposed surfaces of the outlet 206 of the vaporizer vessel. In some embodiments, the protective surface treatment covers at least a portion of the surfaces defining the interior volume 208 of the vaporizer vessel 200. In some embodiments, the protective surface treatment covers at least a portion of the gas-exposed surfaces of the lid 214. In some embodiments, the protective surface treatment covers at least a portion of the gas exposed surfaces of the at least one tray 210. In some embodiments, the protective surface treatment covers at least a portion of the gas exposed surfaces of the base 216 of the at least one tray. In some embodiments, the protective surface treatment covers at least a portion of the top surface of the base 216 of the at least one tray. In some embodiments, the protective surface treatment covers at least a portion of the bottom surface of the base 216 of the at least one tray. In some embodiments, the protective surface treatment covers at least a portion of the gas exposed surfaces of the sidewall of the at least one tray 210. In some embodiments, any one or more of the protective surface treatments on any one or more of the components of the vaporizer vessel 200 are the same and/or different.

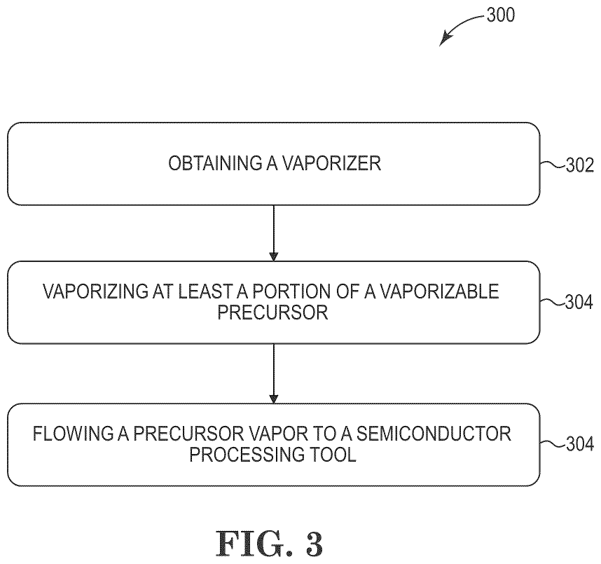

FIG. 3 is a schematic diagram of a flowchart of a method of precursor delivery, according to some embodiments. As shown in FIG. 3, in some embodiments, the method of precursor delivery comprises obtaining 302 a precursor delivery system. In some embodiments, the method of precursor delivery comprises vaporizing 304 at least a portion of the vaporizable precursor to produce a precursor vapor. In some embodiments, the method of precursor delivery comprises flowing 306 the precursor vapor from the vaporizer vessel to a semiconductor processing tool.

At step 302, in some embodiments, the method of precursor delivery comprises obtaining a precursor delivery system. Any of the precursor delivery systems disclosed herein may be used without departing from the scope of this disclosure.

For example, in some embodiments, the precursor delivery system comprises a vaporizer vessel containing a vaporizable precursor and at least one protective surface treatment covering at least a portion of at least one gas-exposed surface of the vaporizer vessel. In some embodiments, the at least one protective surface treatment covers a sufficient amount of the at least one gas-exposed surface of the precursor delivery system to reduce an amount of at least one contaminant in the precursor vapor as compared to a precursor vapor produced by a precursor delivery system without the at least one protective surface treatment.

At step 304, in some embodiments, the method of precursor delivery comprises vaporizing at least a portion of the vaporizable precursor to produce a precursor vapor. In some embodiments, the vaporizing comprises heating the vaporizer vessel. In some embodiments, the vaporizing comprises heating the vaporizable precursor. In some embodiments, the vaporizing comprises pressurizing the vaporizer vessel. In some embodiments, the vaporizing comprises depressurizing the vaporizer vessel. In some embodiments, the vaporizing comprises flowing a carrier gas into and/or through the vaporizer vessel. In some embodiments, the vaporizing comprises flowing an inert gas into and/or through the vaporizer vessel.

In some embodiments, the vaporizing is performed at a temperature of 100° C. to 1000° C., or any range or subrange between 100° C. and 1000° C. For example, in some embodiments, the vaporizing is performed at a temperature of 100° C. to 900° C., 100° C. to 800° C., 100° C. to 700° C., 100° C. to 600° C., 100° C. to 500° C., 100° C. to 400° C., 100° C. to 300° C., 100° C. to 200° C., 200° C. to 1000° C., 300° C. to 1000° C., 400° C. to 1000° C., 500° C. to 1000° C., 600° C. to 1000° C., 700° C. to 1000° C., 800° C. to 1000° C., or 900° C. to 1000° C. In some embodiments, the vaporizing is performed at a temperature of 120° C. to 200° C., 120° C. to 190° C., 120° C. to 180° C., 120° C. to 170° C., 120° C. to 160° C., 120° C. to 150° C., 120° C. to 140° C., 120° C. to 130° C., 130° C. to 200° C., 140° C. to 200° C., 150° C. to 200° C., 160° C. to 200° C., 170° C. to 200° C., 180° C. to 200° C., or 190° C. to 200° C.

In some embodiments, the vaporizing is performed at a pressure of 0.01 Torr to 760 Torr, or any range or subrange between 0.01 Torr and 760 Torr. In some embodiments, for example, the vaporizing is performed at a pressure in a range of 0.01 Torr to 750 Torr, 0.01 Torr to 700 Torr, 0.01 Torr to 650 Torr, 0.01 Torr to 600 Torr, 0.01 Torr to 550 Torr, 0.01 Torr to 500 Torr, 0.01 Torr to 450 Torr, 0.01 Torr to 400 Torr, 0.01 Torr to 350 Torr, 0.01 Torr to 300 Torr, 0.01 Torr to 250 Torr, 0.01 Torr to 200 Torr, 0.01 Torr to 150 Torr, 0.01 Torr to 100 Torr, 0.01 Torr to 50 Torr, 0.01 Torr to 25 Torr, 0.01 Torr to 10 Torr, 0.01 Torr to 5 Torr, 0.01 Torr to 1 Torr, 0.01 Torr to 0.1 Torr, 50 Torr to 760 Torr, 100 Torr to 760 Torr, 150 Torr to 760 Torr, 200 Torr to 760 Torr, 250 Torr to 760 Torr, 300 Torr to 760 Torr, 350 Torr to 760 Torr, 400 Torr to 760 Torr, 450 Torr to 760 Torr, 500 Torr to 760 Torr, 550 Torr to 760 Torr, 600 Torr to 760 Torr, 650 Torr to 760 Torr, or 700 Torr to 760 Torr.

At step 304, in some embodiments, the method of precursor delivery comprises flowing 306 the precursor vapor from the vaporizer vessel to a semiconductor processing tool. In some embodiments, the flowing comprises pumping the precursor vapor from the vaporizer vessel and/or to the semiconductor processing tool. In some embodiments, the flowing comprises applying a vacuum so as to flow the precursor vapor from the vaporizer vessel to the semiconductor processing tool. In some embodiments, the flowing comprises discharging the precursor vapor from the vaporizer vessel, for example, through an outlet. In some embodiments, the flowing comprises flowing the precursor vapor through a gas supply line fluidly coupled to a semiconductor processing tool and the vaporizer vessel. In some embodiments, the flowing comprises flowing the precursor vapor through at least one filter located in the gas supply line. In some embodiments, the flowing comprises flowing the precursor vapor through a valve assembly fluidly coupling the vaporizer vessel and the gas supply line.

In some embodiments, the semiconductor processing tool comprises an ion implantation device.

### Example 1

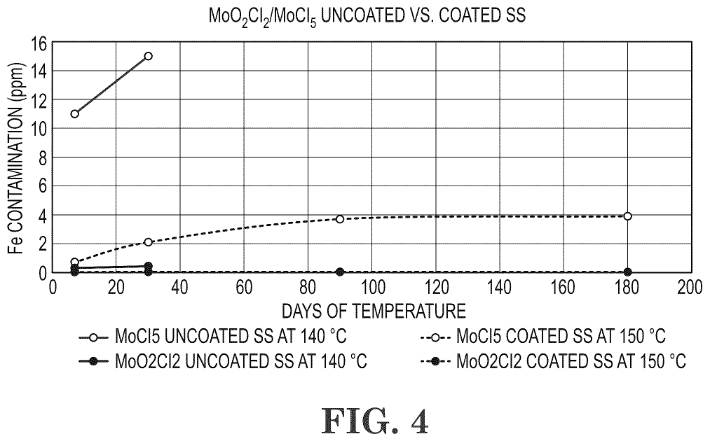

Iron contamination levels in MoO₂Cl₂ precursor vapors and MoCl₅ precursor vapors, produced by uncoated precursor delivery systems containing stainless steel gas-exposed surfaces and produced by coated precursor delivery systems, were measured at elevated temperatures, 140° C. and 150° C., and compared. The coated precursor delivery systems included Al₂O₃ coatings on gas-exposed surfaces. As shown in FIG. 4, which is a graphical view illustrating iron contamination levels in molybdenum-containing precursors in coated versus uncoated systems, coated precursor delivery systems reduced metals contamination at elevated temperatures for both the MoO₂Cl₂ precursor vapor and the MoCl₅ precursor vapor. Relative to the coated precursor delivery systems, the uncoated precursor delivery systems showed significant increases in iron contamination at 140° C.

### ASPECTS

Various Aspects are described below. It is to be understood that any one or more of the features recited in the following Aspect(s) can be combined with any one or more other Aspect(s).

Aspect 1. A precursor delivery system comprising:
a vaporizer vessel configured to contain a vaporizable precursor that, when vaporized, produces a precursor vapor; and
at least one protective surface treatment;
   wherein the at least one protective surface treatment covers a sufficient amount of at least one gas-exposed surface of the precursor delivery system to reduce an amount of at least one contaminant in the precursor vapor as compared to a precursor vapor produced by a precursor delivery system without the at least one protective surface treatment.

Aspect 2. The precursor delivery system according to Aspect 1, wherein the vaporizable precursor comprises a molybdenum-containing source reagent.

Aspect 3. The precursor delivery system according to any one of Aspects 1-2, wherein the precursor vapor comprises MoO₂Cl₂ vapor.

Aspect 4. The precursor delivery system according to any one of Aspects 1-3, wherein the precursor vapor comprises MoCl₅ vapor.

Aspect 5. The precursor delivery system according to any one of Aspects 1-4, wherein the precursor vapor comprises less than 10 ppm of at least one contaminant after 180 days exposure at a temperature of at least 140° C.

Aspect 6. The precursor delivery system according to any one of Aspects 1-5, wherein the at least one protective surface treatment covers all gas-exposed surfaces of the precursor delivery system.

Aspect 7. The precursor delivery system according to any one of Aspects 1-6, wherein the at least one protective surface treatment covers all gas-exposed surfaces of the vaporizer vessel.

Aspect 8. The precursor delivery system according to any one of Aspects 1-7, further comprising:
a gas supply line fluidly coupling the vaporizer vessel to a semiconductor processing tool,
   wherein at least a portion of at least one gas-exposed surface of the gas supply line is covered by the at least one protective surface treatment.

Aspect 9. The precursor delivery system according to Aspect 8, wherein the at least one protective surface treatment covers all gas-exposed surfaces of the gas supply line.

Aspect 10. The precursor delivery system according to Aspect 8, further comprising:
at least one filter located in the gas supply line,
   wherein at least a portion of at least one gas-exposed surface of the at least one filter is covered by the at least one protective surface treatment.

Aspect 11. The precursor delivery system according to Aspect 10, wherein the at least one protective surface treatment covers all gas-exposed surfaces of the at least one filter.

Aspect 12. The precursor delivery system according to Aspect 8, further comprising:
a valve assembly fluidly coupling the vaporizer vessel and the gas supply line,
   wherein at least a portion of at least one gas-exposed surface of the valve assembly is covered by the at least one protective surface treatment.

Aspect 13. The precursor delivery system according to Aspect 12, wherein the at least one protective surface treatment covers all gas-exposed surfaces of the valve assembly.

Aspect 14. The precursor delivery system according to any one of Aspects 1-13, wherein the at least one protective surface treatment comprises at least one of a coating, a surface modified region, or any combination thereof.

Aspect 15. A method comprising:
obtaining a precursor delivery system, the precursor delivery system comprising:
   a vaporizer vessel containing a vaporizable precursor; and
   at least one protective surface treatment covering at least a portion of at least one gas-exposed surface of the vaporizer vessel;
vaporizing at least a portion of the vaporizable precursor to produce a precursor vapor; and
flowing the precursor vapor from the vaporizer vessel to a semiconductor processing tool,
   wherein the at least one protective surface treatment covers a sufficient amount of the at least one gas-exposed surface of the precursor delivery system to reduce an amount of at least one contaminant in the precursor vapor as compared to a precursor vapor produced by a precursor delivery system without the at least one protective surface treatment.

Aspect 16. The method according to Aspect 15, wherein the precursor vapor comprises a MoO₂Cl₂ vapor.

Aspect 17. The method according to any one of Aspects 15-16, wherein the precursor vapor comprises a MoCl₅ vapor.

Aspect 18. The method according to any one of Aspects 15-17, wherein the precursor vapor comprises less than 10 ppm of at least one of an iron contaminant, a nickel contaminant, or any combination thereof.

Aspect 19. The method according to any one of Aspects 15-18, wherein the vaporizable precursor is vaporized at a temperature of 145° C. or greater.

Aspect 20. The method according to any one of Aspects 15-19, wherein the vaporizable precursor is vaporized at a pressure of 0.01 Torr to 760 Torr.

It is to be understood that changes may be made in detail, especially in matters of the construction materials employed and the shape, size, and arrangement of parts without departing from the scope of the present disclosure. This Specification and the embodiments described are examples, with the true scope and spirit of the disclosure being indicated by the claims that follow.

What is claimed is:

1. A precursor delivery system comprising:
a vaporizer vessel configured to contain a vaporizable precursor that, when vaporized, produces a precursor vapor; and
at least one protective surface treatment;
wherein the at least one protective surface treatment covers a sufficient amount of at least one gas-exposed surface of the precursor delivery system to reduce an amount of at least one contaminant in the precursor vapor as compared to a precursor vapor produced by a precursor delivery system without the at least one protective surface treatment.

2. The precursor delivery system of claim 1, wherein the vaporizable precursor comprises a molybdenum-containing source reagent.

3. The precursor delivery system of claim 1, wherein the precursor vapor comprises MoO₂Cl₂ vapor.

4. The precursor delivery system of claim 1, wherein the precursor vapor comprises MoCl₅ vapor.

5. The precursor delivery system of claim 1, wherein the precursor vapor comprises less than 10 ppm of at least one contaminant after 180 days exposure at a temperature of at least 140° C.

6. The precursor delivery system of claim 1, wherein the at least one protective surface treatment covers all gas-exposed surfaces of the precursor delivery system.

7. The precursor delivery system of claim 1, wherein the at least one protective surface treatment covers all gas-exposed surfaces of the vaporizer vessel.

8. The precursor delivery system of claim 1, further comprising:
a gas supply line fluidly coupling the vaporizer vessel to a semiconductor processing tool,
wherein at least a portion of at least one gas-exposed surface of the gas supply line is covered by the at least one protective surface treatment.

9. The precursor delivery system of claim 8, wherein the at least one protective surface treatment covers all gas-exposed surfaces of the gas supply line.

10. The precursor delivery system of claim 8, further comprising:
at least one filter located in the gas supply line,
wherein at least a portion of at least one gas-exposed surface of the at least one filter is covered by the at least one protective surface treatment.

11. The precursor delivery system of claim 10, wherein the at least one protective surface treatment covers all gas-exposed surfaces of the at least one filter.

12. The precursor delivery system of claim 8, further comprising:
a valve assembly fluidly coupling the vaporizer vessel and the gas supply line,
wherein at least a portion of at least one gas-exposed surface of the valve assembly is covered by the at least one protective surface treatment.

13. The precursor delivery system of claim 12, wherein the at least one protective surface treatment covers all gas-exposed surfaces of the valve assembly.

14. The precursor delivery system of claim 1, wherein the at least one protective surface treatment comprises at least one of a coating, a surface modified region, or any combination thereof.

15. The precursor delivery system of claim 1, wherein the at least one protective surface treatment further covers at least one non-gas-exposed surface of the precursor delivery system.

16. A method comprising:
obtaining a precursor delivery system, the precursor delivery system comprising:
a vaporizer vessel containing a vaporizable precursor; and
at least one protective surface treatment covering at least a portion of at least one gas-exposed surface of the vaporizer vessel;
vaporizing at least a portion of the vaporizable precursor to produce a precursor vapor; and
flowing the precursor vapor from the vaporizer vessel to a semiconductor processing tool,
wherein the at least one protective surface treatment covers a sufficient amount of the at least one gas-exposed surface of the precursor delivery system to reduce an amount of at least one contaminant in the precursor vapor as compared to a precursor vapor produced by a precursor delivery system without the at least one protective surface treatment.

17. The method of claim 16, wherein the precursor vapor comprises a MoO₂Cl₂ vapor.

18. The method of claim 16, wherein the precursor vapor comprises a MoCl₅ vapor.

19. The method of claim 16, wherein the precursor vapor comprises less than 10 ppm of at least one of an iron contaminant, a nickel contaminant, or any combination thereof.

20. The method of claim 16, wherein the vaporizable precursor is vaporized at a temperature of 145° C. or greater.
